(19) United States
(12) Patent Application Publication
(10) Pub. No.: US 2025/0080065 A1
(43) Pub. Date: Mar. 6, 2025

(54) AMPLIFIER CIRCUIT

(71) Applicant: Sumitomo Electric Device Innovations, Inc., Yokohama-shi (JP)

(72) Inventor: Takashi SUMIYOSHI, Yokohama-shi (JP)

(73) Assignee: Sumitomo Electric Device Innovations, Inc., Yokohama-shi (JP)

(21) Appl. No.: 18/774,074

(22) Filed: Jul. 16, 2024

(30) Foreign Application Priority Data
Sep. 5, 2023 (JP) 2023-143831

(51) Int. Cl. H03F 3/21; H03F 1/02

(52) U.S. Cl. CPC H03F 3/211; H03F 1/0288; H03F 2200/552

(57) ABSTRACT

An amplifier circuit includes a divider that divides an input signal into a first signal and a second signal, a first amplifier that amplifies the first signal and output a third signal to a first node, a second amplifier that amplifies the second signal and outputs a fourth signal to a second node, a combiner that combines the third signal and the fourth signal and outputs a combined signal to an output terminal as an output signal, and a processing circuit that includes an input node to which the first and the second nodes are electrically coupled, and allows a signal having a frequency lower than an operating band of the first amplifier and the second amplifier to pass through a reference potential, wherein a coupling degree between the first node and the input node is larger than a coupling degree between the second node and the input node.

### CROSS REFERENCE TO RELATED APPLICATIONS

This application claims priority based on Japanese Patent Application No. 2023-143831 filed on Sep. 5, 2023, and the entire contents of the Japanese patent applications are incorporated herein by reference.

### FIELD

A certain aspect of the embodiments is related to an amplifier circuit.

### BACKGROUND

In an amplifier circuit in which two amplifiers such as a Doherty amplifier circuit are connected in parallel, it is known that a VBW (Video Bandwidth) circuit is provided at each of output terminals of the two amplifiers (for example, Patent Document 1: Japanese Laid-Open Patent Application No. 2022-138983).

### SUMMARY

An amplifier circuit according to the present disclosure includes: a divider that divides an input signal into a first signal and a second signal; a first amplifier that amplifies the first signal and output an amplified signal to a first node as a third signal; a second amplifier that amplifies the second signal and outputs an amplified signal to a second node as a fourth signal; a combiner that combines the third signal and the fourth signal and outputs a combined signal to an output terminal as an output signal; and a processing circuit that includes an input node to which the first node and the second node are electrically coupled, and allows a signal having a frequency lower than an operating band of the first amplifier and the second amplifier to pass through a reference potential, wherein a coupling degree between the first node and the input node is larger than a coupling degree between the second node and the input node.

### BRIEF DESCRIPTION OF DRAWINGS

FIG. 1 is a block diagram of an amplifier circuit according to a first embodiment.

FIG. 2 is a schematic diagram illustrating a first example of a coupler in the first embodiment.

FIG. 3 is a schematic diagram illustrating a second example of a coupler in the first embodiment.

FIG. 4 is a circuit diagram of a first example of a VBW circuit according to the first embodiment.

FIG. 5 is a circuit diagram of a second example of a VBW circuit according to the first embodiment.

FIG. 6 is a circuit diagram of a third example of a VBW circuit according to the first embodiment.

FIG. 7 is a block diagram of an amplifier circuit according to a first comparative example.

FIG. 8 is a block diagram of an amplifier circuit according to a first modification of the first embodiment.

FIG. 9 is a block diagram of a region around a coupler and a processing circuit in the amplifier circuit according to the first modification of the first embodiment.

FIG. 10 is a block diagram of an amplifier circuit according to a second modification of the first embodiment.

FIG. 11 is a block diagram of a region around a coupler and a processing circuit in an amplifier circuit according to a second modification of the first embodiment.

FIG. 12 is a block diagram of an amplifier circuit according to a second embodiment.

FIG. 13 is a diagram illustrating drain efficiencies with respect to input powers of respective amplifiers in the second embodiment.

FIG. 14 is a block diagram of an amplifier circuit according to a first modification of the second embodiment.

FIG. 15 is a block diagram of an amplifier circuit according to a third embodiment.

FIG. 16 is a diagram illustrating an amplifier circuit in simulation.

FIG. 17 is a diagram illustrating pass characteristics of a sample A in the simulation.

FIG. 18 is a diagram illustrating pass characteristics of a sample B in the simulation.

FIG. 19 is a diagram illustrating isolation characteristics of the samples A and B in the simulation.

### DETAILED DESCRIPTION OF EMBODIMENTS

The VBW circuit (also called a differential frequency short circuit, video bypass circuit or envelope frequency termination circuit) is a circuit that processes frequencies lower than the operating band of the amplifier. If the VBW circuit is provided for each amplifier, the size of the amplifier circuit is increased. If a single VBW circuit is provided in common to two amplifiers, the characteristics deteriorate.

The present disclosure has been made in view of the above problems, and an object thereof is to suppress deterioration of the characteristics.

### Details of Embodiments of the Present Disclosure

First, the contents of the embodiments of this disclosure are listed and explained.
(1) An amplifier circuit according to the present disclosure includes: a divider that divides an input signal into a first signal and a second signal; a first amplifier that amplifies the first signal and output an amplified signal to a first node as a third signal; a second amplifier that amplifies the second signal and outputs an amplified signal to a second node as a fourth signal; a combiner that combines the third signal and the fourth signal and outputs a combined signal to an output terminal as an output signal; and a processing circuit that includes an input node to which the first node and the second node are electrically coupled, and allows a signal having a frequency lower than an operating band of the first amplifier and the second amplifier to pass through a reference potential, wherein a coupling degree between the first node and the input node is larger than a coupling degree between the second node and the input node. This makes it possible to reduce the insertion loss of the operating band in the second amplifier. In addition, the isolation characteristics between the first amplifier and the second amplifier can be improved.
(2) In the above (1), the first node and the input node may be electrically connected to each other, and the second node and the input node may be electromagnetic-field coupled in a coupler. This makes it possible to make a coupling degree between the second node and the input node smaller than a coupling degree between the first node and the input node.
(3) In the above (2), the coupler may include a first line electrically connected to the first node and the input node. and a second line electrically connected to the second node, not electrically connected to the first line, and electromagnetic-field coupled to the first line. This allows the electromagnetic field coupling between the second node and the input node in the coupler.
(4) In any one of the above (1) to (3), the processing circuit may include a capacitor connected in series between the input node and the reference potential. Thereby, the processing circuit can suppress the signals in the low frequency band of the first amplifier and the second amplifier.
(5) In the above (4), an absolute value of an impedance at a center frequency of the operating band between the first node and the capacitor may be larger than an absolute value of an impedance of the capacitor at a frequency corresponding to a bandwidth of the operating band, and an absolute value of an impedance at a center frequency between the second node and the capacitor may be larger than the absolute value of the impedance of the capacitor at the frequency corresponding to the bandwidth of the operating band. This makes it possible to reduce the insertion loss of the operating band in the second amplifier. In addition, the isolation characteristics between the first amplifier and the second amplifier can be improved.
(6) In any one of the above (1) to (5), the second amplifier may be operable with a lower input power than the first amplifier. This makes it possible to suppress the insertion loss of the second amplifier having a small distortion. In addition, the isolation characteristics between the first amplifier and the second amplifier can be improved.
(7) In any one of the above (1) to (6), the amplifier circuit may be a Doherty amplifier circuit, the first amplifier may be a peak amplifier, and the second amplifier may be a main amplifier. This makes it possible to suppress the insertion loss of the main amplifier. In addition, the isolation characteristics between the main amplifier and the peak amplifier can be improved.
(8) In any one of the above (1) to (6), the amplifier circuit further may include a third amplifier. The divider may divide the input signal into the first signal, the second signal, and a fifth signal, the third amplifier may amplify the fifth signal and output an amplified signal to a third node as a sixth signal, and the combiner may combine the third signal, the fourth signal, and the sixth signal, and output a combined signal as the output signal. This makes it possible to suppress the signals in the low frequency band of at least two amplifiers.
(9) In the above (8), a node electrically coupled to the input node may not be provided between the third amplifier and the combiner. This makes it possible to suppress the insertion loss of the third amplifier. In addition, the isolation characteristic between the third amplifier and the first and second amplifiers can be improved.
(10) In the above (8), the third node and the input node may be electrically coupled to each other, and a coupling degree between the third node and the input node may be smaller than the coupling degree between the second node and the input node. This makes it possible to suppress the signals in the low frequency band of the first amplifier, the second amplifier, and the third amplifier. In addition, the insertion loss of the third amplifier can be suppressed. In addition, the isolation characteristics between the third amplifier and the first and second amplifiers can be improved.
(11) In the above (9) or (10), the second amplifier may be operable with a lower input power than the first amplifier, and the third amplifier may be operable with a lower input power than the second amplifier. This makes it possible to suppress the insertion loss of the third amplifier having a small distortion. In addition, the isolation characteristics between the third amplifier and the first and second amplifiers can be improved.
(12) In any one of the above (9) to (11), the amplifier circuit may be a Doherty amplifier circuit, the third amplifier may be a main amplifier, and the first amplifier and the second amplifier may be peak amplifiers. This makes it possible to suppress the insertion loss of the main amplifier. In addition, the isolation characteristics between the main amplifier and the peak amplifiers can be improved.

Specific examples of an amplifier circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

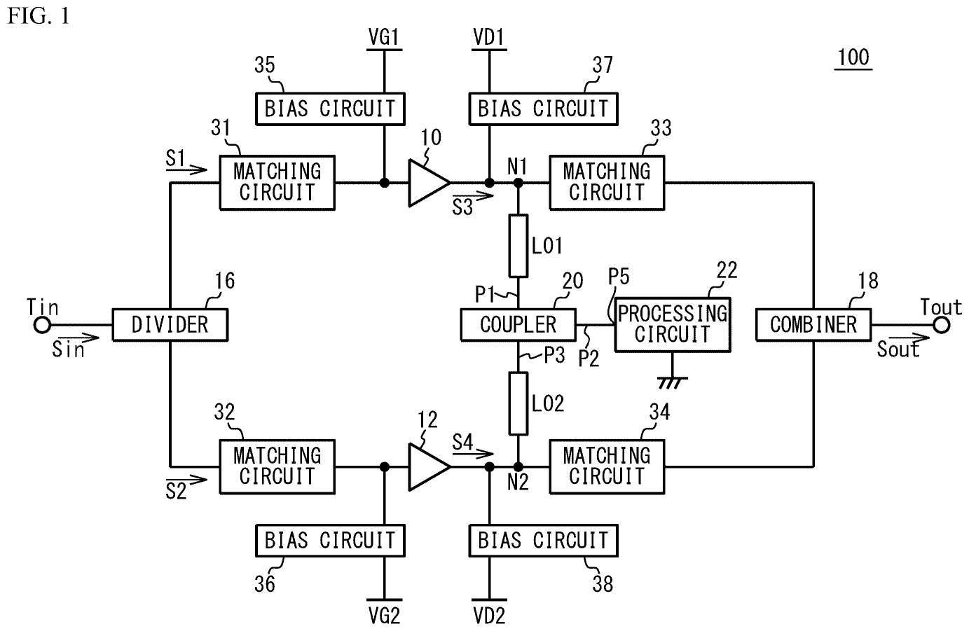

A high-output high-frequency amplifier circuit used in a base station of mobile communication will be described as an example of an amplifier circuit. In this case, the frequency of the high-frequency signal is, for example, 0.5 GHz or more and 10 GHz or less. FIG. 1 is a block diagram of an amplifier circuit according to a first embodiment. As illustrated in FIG. 1, an amplifier circuit 100 includes amplifiers 10 and 12, a divider 16, a combiner 18, a coupler 20, a processing circuit 22, lines L01 and L02, matching circuits 31 to 34, and bias circuits 35 to 38.

The amplifiers 10 and 12 are connected in parallel between an input terminal Tin and an output terminal Tout. A high-frequency signal is input to the input terminal Tin as an input signal Sin. The divider 16 divides the input signal Sin input to the input terminal Tin into signals S1 (first signal) and S2 (second signal). The divider 16 is, for example, a Wilkinson-type divider.

The signal S1 passes through the matching circuit 31 and is input to the amplifier 10. The matching circuit 31 matches an impedance when the matching circuit 31 is seen from the divider 16 with an impedance when the amplifier 10 is seen from the matching circuit 31. The amplifier 10 (first amplifier) amplifies the signal S1 and outputs an amplified signal S3 (third signal). The signal S3 amplified by the amplifier 10 passes through the matching circuit 33 and is output to the combiner 18. The matching circuit 33 matches an impedance when the matching circuit 33 is seen from the amplifier 10 with an impedance when the combiner 18 is seen from the matching circuit 33. The bias circuit 35 is connected between a bias terminal and a node between the matching circuit 31 and the amplifier 10. The bias circuit 35 supplies a gate bias voltage VG1 to the amplifier 10 to suppress the leakage of the signal S1 to the bias terminal. The bias circuit 37 is connected between and a bias terminal and a node between the amplifier 10 and the matching circuit 33. The bias circuit 37 supplies a drain bias voltage VD1 to the amplifier 10 to suppress the leakage of the signal S3 to the bias terminal.

The signal S2 passes through the matching circuit 32 and is input to the amplifier 12. The matching circuit 32 matches an impedance when the matching circuit 32 is seen from the divider 16 with an impedance when the amplifier 12 is seen from the matching circuit 32. The amplifier 12 (second amplifier) amplifies the signal S2 and outputs an amplified signal S4 (fourth signal). The signal S4 amplified by the amplifier 12 passes through the matching circuit 34 and is output to the combiner 18. The matching circuit 34 matches an impedance when the matching circuit 34 is seen from the amplifier 12 with an impedance when the combiner 18 is seen from the matching circuit 34. The bias circuit 36 is connected between a bias terminal and a node between the matching circuit 32 and the amplifier 12. The bias circuit 36 supplies a gate bias voltage VG2 to the amplifier 12 to suppress the leakage of the signal S2 to the bias terminal. The bias circuit 38 is connected between a bias terminal and a node between the amplifier 12 and the matching circuit 34. The bias circuit 38 supplies a drain bias voltage VD2 to the amplifier 12 to suppress the leakage of the signal S4 to the bias terminal. The combiner 18 combines the signals S3 and S4 and outputs a combined signal to the output terminal Tout as an output signal Sout.

The amplifiers 10 and 12 are, for example, field effect transistors (FETs). Each of the amplifiers 10 and 12 has a source connected to ground, a gate to which a high-frequency signal is input, and a drain to which a signal is output. The FET is, for example, a GaN HEMT (Gallium Nitride High Electron Mobility Transistor) or an LDMOS (Laterally Diffused Metal Oxide Semiconductor).

A first end of the line L01 is electrically connected to a node N1 (first node) between the amplifier 10 and the matching circuit 33. A first end of the line L02 is electrically connected to a node N2 (second node) between the amplifier 12 and the matching circuit 34. An input port P1 of the coupler 20 is electrically connected to a second end of the line L01. A coupling port P3 of the coupler 20 is electrically connected to a second end of the line L02. An output port P2 of the coupler 20 is electrically connected to an input node P5 of the processing circuit 22. The processing circuit 22 passes a signal having a frequency lower than the operating band (referred to as a low frequency band) in signals input to the input node P5, to a reference potential.

### First Example of Coupler

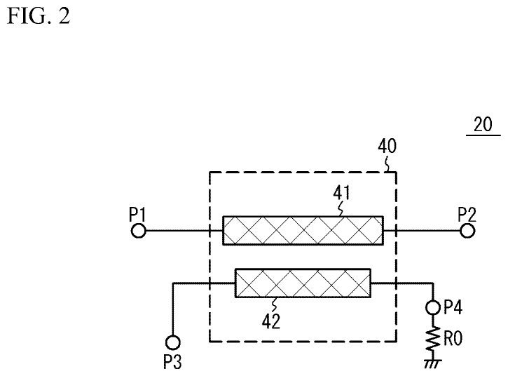

FIG. 2 is a schematic diagram illustrating a first example of the coupler in the first embodiment. As illustrated in FIG. 2, the coupler 20 is a directional coupler. Lines 41 and 42 are provided on a dielectric substrate 40. The dielectric substrate 40 is, for example, a circuit substrate on which the amplifiers 10 and 12 are mounted or a substrate of a chip mounted on a package on which the amplifiers 10 and 12 are mounted. The lines 41 and 42 are signal lines of, for example, microstrip lines or coplanar lines. The lines 41 and 42 form transmission lines with a reference potential such as ground. The input port P1 is connected to a first end of the line 41, and the output port P2 is connected to a second end of the line 41. The coupling port P3 is connected to a first end of the line 42, and an isolation port P4 is connected to a second end of the line 42. The isolation port P4 is terminated by a reference impedance R0 (e.g., 50Ω). The lines 41 and 42 are magnetically coupled. The high frequency signal input to the input port P1 is output to the output port P2. A part of the high frequency signal input to the coupling port P3 is output to the output port P2 in accordance with a coupling degree between the lines 41 and 42.

### Second Example of Coupler

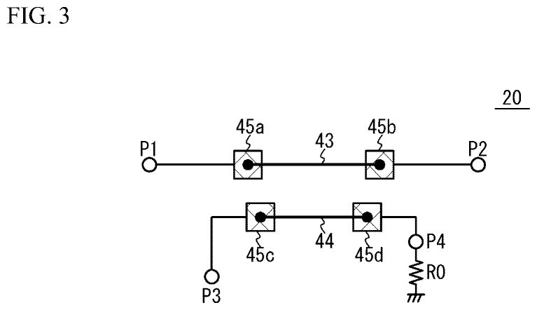

FIG. 3 is a schematic diagram illustrating a second example of the coupler in the first embodiment. As illustrated in FIG. 3, pads 45a to 45d are provided. The pads 45a to 45d are, for example, pads on the upper surface of a chip mounted on a package. The pad 45a is electrically connected to the input port P1, the pad 45b is electrically connected to the output port P2, the pad 45c is electrically connected to the coupling port P3, and the pad 45d is electrically connected to the isolation port P4. A bonding wire 43 electrically connects the pads 45a and 45b. A bonding wire 44 electrically connects the pads 45c and 45d. The bonding wires 43 and 44 are provided adjacent to each other and magnetically coupled. The high frequency signal input to the input port P1 is output to the output port P2. A part of the high-frequency signal input to the coupling port P3 is output to the output port P2 in accordance with a coupling degree between the bonding wires 43 and 44.

### First Example of VBW Circuit

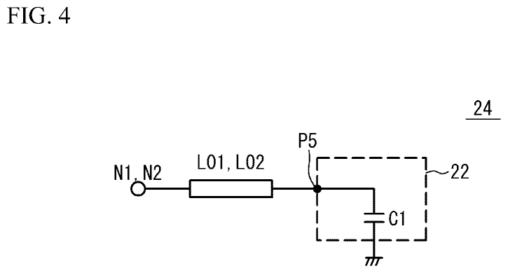

FIG. 4 is a circuit diagram of a first example of a VBW circuit according to the first embodiment. In FIG. 4, the coupler 20 is not illustrated. A VBW circuit 24 includes the line L01 or L02 and the processing circuit 22. The first end of the line L01 or L02 is electrically connected to the node N1 or N2, and the second end of the line L01 or L02 is electrically connected to the input node P5. The processing circuit 22 includes a capacitor C1 connected in series between the input node P5 and the reference potential.

The VBW circuit 24 is a circuit for improving a video bandwidth (VBW). The video bandwidth is used as an index to represent the bandwidth of distortion. If the VBW is small, when a 3rd order InterModulation distortion (IMD3) of two tone signal corresponding to the bandwidth of the amplifier (for example, 400 MHZ) is measured, a difference in signal intensity occurs between the IMD3 component on the low frequency side and the IMD3 component on the high frequency side. When the asymmetry occurs in the IMD3 as described above, even if distortion compensation is performed by DPD (Digital Predistortion), an amount of improvement in distortion is reduced, and sufficient distortion characteristics cannot be obtained. As a cause of the asymmetry of the IMD3, a second order intermodulation distortion IMD2 component generated in a difference frequency component of the two tone signal is known. Therefore, the VBW circuit 24 is provided to reduce an impedance in the low frequency band between the nodes N1 and N2 and the reference potential. This increases the video bandwidth and suppresses the IMD2 component. This improves the asymmetry of the IMD3, and the DPD can perform sufficient distortion compensation.

The lines L01 and L02 are inductors or transmission lines. The lines L01 and L02 suppress leakage of the signal in the operating band from nodes N1 and N2 to the coupler 20.

Therefore, the impedances of the lines L01 and L02 are high at the frequency of the operating band. The capacitor C1 allows the signal in a low frequency band lower than the operating band from the input node P5 to pass through to the reference potential. Therefore, the capacitor C1 has a large capacitance so as to have a low impedance in the low frequency band (for example, at a frequency corresponding to a bandwidth). The operating band is, for example, between 0.5 GHZ and 10 GHz, and the bandwidth of the operating band is, for example, greater than 0 MHz and equal to or less than 400 MHZ. The frequency of the signal that the processing circuit 22 allows to pass through to the reference potential is lower than the operating band of the amplifiers 10 and 12, for example, and is equal to or lower than ½ of the center frequency of the operating band or equal to or lower than ⅕ of the center frequency of the operating band.

### Second Example of VBW Circuit

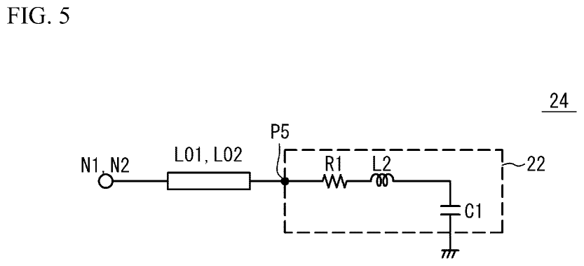

FIG. 5 is a circuit diagram of a second example of the VBW circuit according to the first embodiment. As illustrated in FIG. 5, a resistor R1 and an inductor L2 are connected in series between the input node P5 and the capacitor C1. A first end of the resistor R1 is electrically connected to the input node P5, a second end of the resistor R1 is electrically connected to a first end of the inductor L2, and a second end of the inductor L2 is electrically connected to a first end of the capacitor C1. The other connection relationships in FIG. 5 are the same as those in FIG. 4. The inductor L2 corresponds to a line such as a bonding wire for electrically connecting the capacitor C1 and the resistor R1. The resistor R1 is a damping resistor. For example, if a capacitor (e.g., parasitic capacitance) is connected in parallel with capacitor C1 and inductor L2, unnecessary resonance may occur. By providing the resistor R1, unnecessary resonance can be suppressed.

### Third Example of VBW Circuit

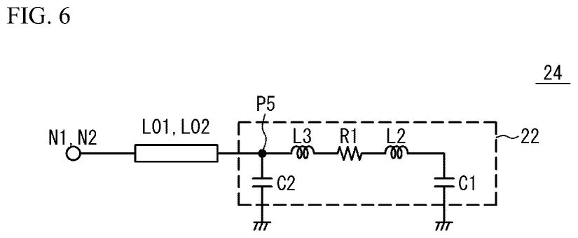

FIG. 6 is a circuit diagram of a third example of the VBW circuit according to the first embodiment. As illustrated in FIG. 6, a first end of an inductor L3 is electrically connected to the input node P5, a second end of the inductor L3 is electrically connected to the first end of the resistor R1, a first end of a capacitor C2 is electrically connected to a node between the inductor L3 and the line L01 or L02, and a second end of the capacitor C2 is electrically connected to the reference potential. The other connection relationships in FIG. 6 are the same as those in FIG. 5.

The inductor L3 corresponds to a line such as a bonding wire for electrically connecting the capacitor C2 and the resistor R1. The capacitor C2 has a capacitance different from the capacitance of the capacitor C1. This makes it possible to increase the frequency band suppressed by the VBW circuit 24. The resistor R1 is a damping resistor for suppressing unnecessary resonance caused by the capacitors C1 and C2.

### First Comparative Example

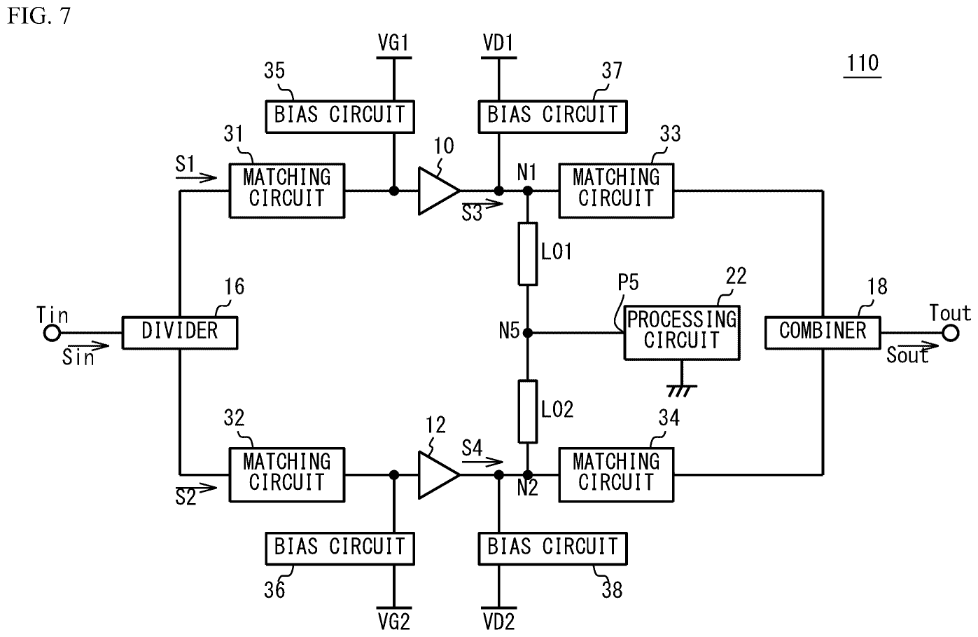

FIG. 7 is a block diagram of an amplifier circuit according to a first comparative example. As illustrated in FIG. 7, an amplifier circuit 110 of the first comparative example 1 is not provided with the coupler 20. The second end of the line L01, the second end of the line L02, and the input node P5 of the processing circuit 22 are electrically connected to a node N5. Accordingly, the signal of the low frequency band in the signals S3 and S4 passes through the node N5 and passes through the processing circuit 22 to reach the reference potential. Therefore, the signal in the low frequency band can be suppressed. However, although the lines L01 and L02 suppress the passage of signals in the operating band, some of the signals in the operating band pass through the lines L01 and L02 and flow to the reference potential. The signal in the low frequency band flows between the nodes N1 and N2. This increases an insertion loss in the operating band of the signals S3 and S4 passing through the nodes N1 and N2. In addition, the isolation in the operating band and the low frequency band between the nodes N1 and N2 is deteriorated. On the other hand, the degrees of suppression of the signals in the low frequency band may not be the same between the signals S3 and S4.

### Description of First Embodiment

In the first embodiment, the processing circuit 22 allows the signal having the frequency lower than the operating band of the amplifiers 10 and 12 to pass through the reference potential. The node N1 is electrically connected to the input port P1, and the node N2 is electrically connected to the coupling port P3. Therefore, the processing circuit 22 is more strongly coupled to the node N1 than to the node N2. Therefore, the processing circuit 22 suppresses the signal in the low frequency band in the signal S4 more than the signal in the low frequency band in the signal S3. On the other hand, the signal in the operating band in the signal S4 does not leak to the reference potential more than the signal in the operating band in the signal S3. Therefore, the insertion loss of the node N2 is smaller than the insertion loss of the node N1. For example, when the distortion of the amplifier 10 is larger than the distortion of the amplifier 12, the asymmetry of the IMD3 is improved by suppressing the signal of the low frequency band in the amplifier 10. On the other hand, in the amplifier 12, the asymmetry of the IMD3 is improved even if the signal in the low frequency band is not suppressed as much as in the amplifier 10. Therefore, the node N2 is electrically connected to the coupling port P3. Thus, the signal in the low frequency band of the amplifier 12 is not suppressed as much as the signal in the low frequency band of the amplifier 10, but the insertion loss of the operating band at the node N2 of the amplifier 12 can be reduced. In addition, the isolation characteristics of the operating band and the low frequency band between the node N1 of the amplifier 10 and the node N2 of the amplifier 12 can be improved.

Further, the VBW circuit 24 can be realized by the lines L01 and L02 and the processing circuit 22. An absolute value of the impedance of each of the lines L01 and L02 at the center frequency of the operating band is made larger than an absolute value of the impedance of the capacitor C1 at the frequency corresponding to the bandwidth of the operating band. Thus, the lines L01 and L02 can suppress leakage of the signals in the operating band in signals S3 and S4 to the reference potential, and the capacitor C1 can allow the signal in the low frequency band to pass through to the reference potential.

### First Modification of First Embodiment

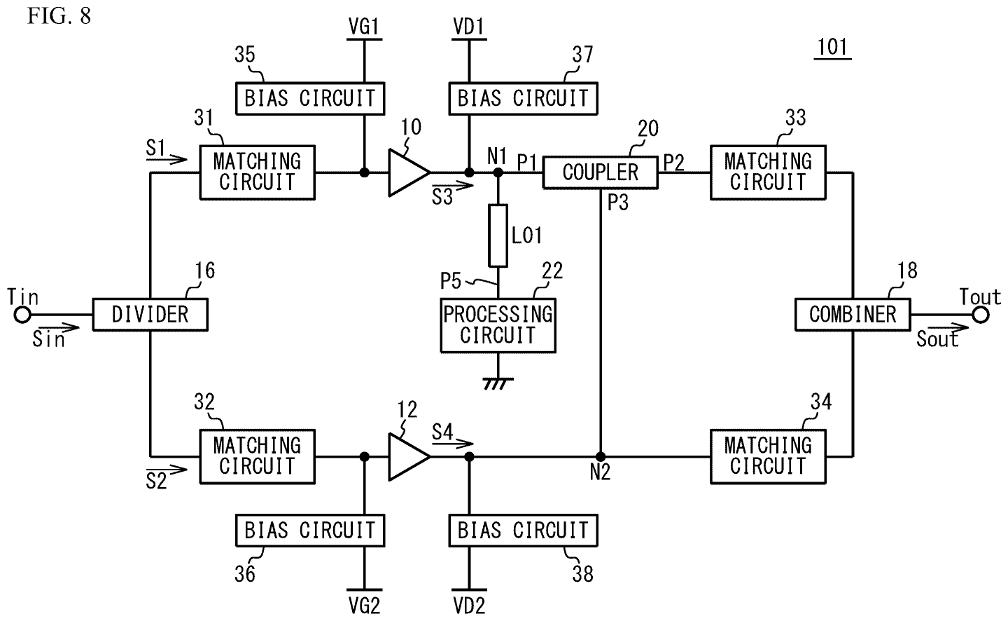

FIG. 8 is a block diagram of an amplifier circuit according to a first modification of the first embodiment. As illustrated in FIG. 8, in an amplifier circuit 101 according to the first modification of the first embodiment, the input node P5 of the processing circuit 22 is electrically connected to the node N1 via the line L01. The input port P1 of the coupler 20 is electrically connected to the node N1, and the output port P2 is electrically connected to the matching circuit 33. The node N2 is electrically connected to the coupling port P3 of the coupler 20. The line L01 and the processing circuit 22 form the VBW circuit 24. The other configurations of the first modification of the first embodiment are the same as those of the first embodiment, and the description thereof is omitted.

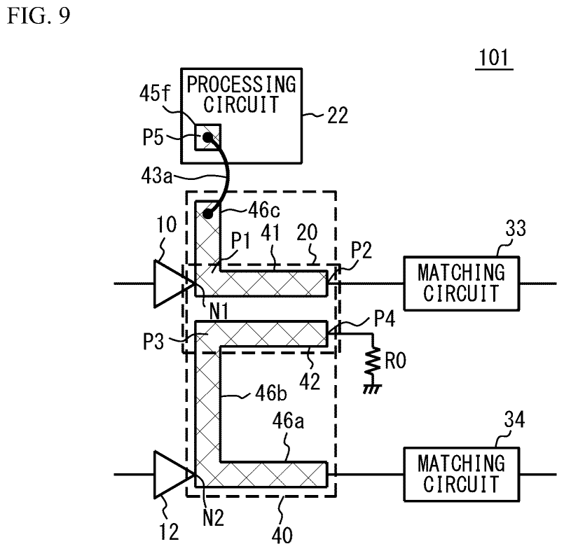

FIG. 9 is a block diagram of a region around the coupler and the processing circuit of the amplifier circuit according to the first modification of the first embodiment. As illustrated in FIG. 9, the lines 41, 42 and 46a to 46c are provided on the dielectric substrate 40. The lines 41, 42 and 46a to 46c are signal lines of transmission lines such as microstrip lines or coplanar lines. The lines 41 and 42 form the coupler 20. The input port P1 corresponding to a first end of the line 41 is electrically connected to the node N1. The output port P2 corresponding to a second end of the line 41 is electrically connected to the matching circuit 33. The coupling port P3 corresponding to a first end of the line 42 is electrically connected to the node N2 via the line 46b. The isolation port P4 corresponding to a second end of the line 42 is connected to the reference potential via the reference impedance R0. The node N2 is electrically connected to the matching circuit 34 through the line 46a. The node N1 is electrically connected to a pad 45f corresponding to the input node P5 of the processing circuit 22 through the line 46c and a bonding wire 43a. The line 46c and the bonding wire 43a correspond to the line L01 in FIG. 8.

The node N1 is electrically connected to the processing circuit 22 without passing through the coupler 20. Therefore, the processing circuit 22 can suppress the signal in the low frequency band at the node N1. The node N2 is connected to the processing circuit 22 through magnetic field coupling between the lines 42 and 41 of the coupler 20. Therefore, although the suppression of the signal in the low frequency band at the node N2 is small, the insertion loss at the node N2 can be suppressed.

### Second Modification of First Embodiment

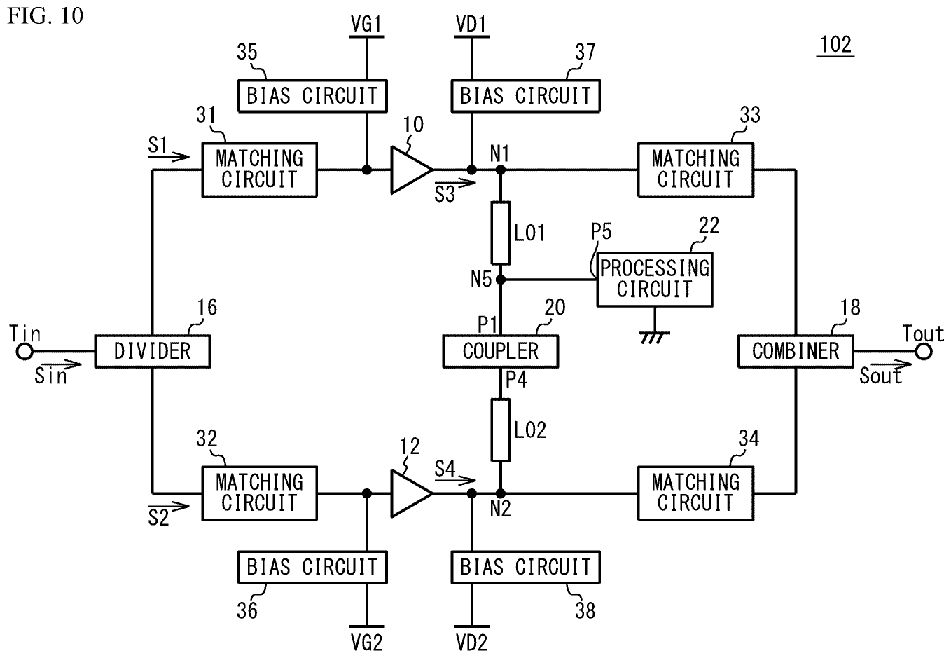

FIG. 10 is a block diagram of an amplifier circuit according to a second modification of the first embodiment. As illustrated in FIG. 10, in an amplifier circuit 102 according to the second modification of the first embodiment, the second end of the line L01 is electrically connected to the node N5. The node N5 is electrically connected to the input node P5 of the processing circuit 22 and the input port P1 of the coupler 20. The second end of the line L02 is electrically connected to the isolation port P4 of the coupler 20. The other configurations of the second modification of the first embodiment are the same as those of the first embodiment, and the description thereof is omitted.

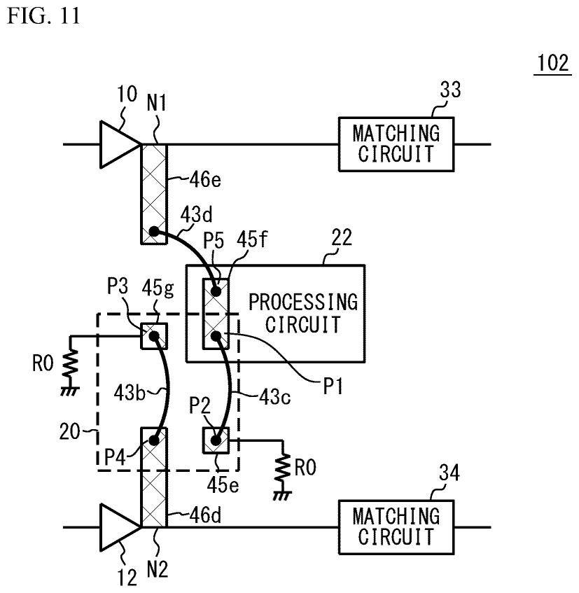

FIG. 11 is a block diagram of a region around the coupler and the processing circuit of the amplifier circuit according to the second modification of the first embodiment. As illustrated in FIG. 11, the node N1 is electrically connected to the pad 45f corresponding to the input node P5 of the processing circuit 22 through a transmission line 46e and a bonding wire 43d. The node N2 is electrically connected to a pad 45g via a transmission line 46d and a bonding wire 43b. The pad 45f is electrically connected to a pad 45e via a bonding wire 43c. The pads 45e and 45g are connected to the reference potential via the reference impedance R0. The bonding wires 43b and 43c correspond to the coupler 20 of FIG. 10. The ends of the pads 45f, 45c, 45g and an end of the transmission line 46d correspond to the input port P1, the output port P2, the coupling port P3 and the isolation port P4, respectively. The transmission line 46e and the bonding wire 43d correspond to the line L01 in FIG. 10, and the transmission line 46d corresponds to the line L02 in FIG. 10.

The node N1 is electrically connected to the processing circuit 22 without passing through the coupler 20. Therefore, the processing circuit 22 can suppress the signal in the low frequency band at the node N1. The node N2 is connected to the processing circuit 22 through magnetic field coupling between the bonding wires 43b and 43c of the coupler 20. Therefore, although the suppression of the signal in the low frequency band at the node N2 is small, the insertion loss at the node N2 can be suppressed.

According to the first embodiment and its modification, the input node P5 of the processing circuit 22 is electrically coupled to the nodes N1 and N2. A coupling degree between the node N1 and the input node P5 is greater than a coupling degree between the node N2 and the input node P5. Thus, the signal in the low frequency band of the amplifier 12 is not suppressed as much as the signal in the low frequency band of the amplifier 10, but the insertion loss of the operating band at the node N2 of the amplifier 12 can be reduced. In addition, the isolation characteristics between the node N1 of the amplifier 10 and the node N2 of the amplifier 12 can be improved.

A difference between the coupling degree between the node N1 and the input node P5 and the coupling degree between the node N2 and the input node P5 can be 1 dB or more, 2 dB or more, or 5 dB or more. From the viewpoint of coupling the node N2 and the input node P5, the difference between the coupling degree between the node N1 and the input node P5 and the coupling degree between the node N2 and the input node P5 can be set to 20 dB or less. The coupling degree between the node N1 and the input node P5 is, for example, 5 dB or more or 3 dB or more. The coupling degree between the node N2 and the input node P5 is, for example, 5 dB or less or 10 dB or less.

As illustrated in FIGS. 2, 3, 9 and 11, the node N1 and the input node P5 are electrically connected to each other. The node N2 and the input node P5 are electromagnetic-field coupled to each other in the coupler 20. This makes it possible to make the coupling degree between the node N2 and the input node P5 smaller than the coupling degree between the node N1 and the input node P5. The electrical connection between the node N1 and the input node P5 means, for example, that the node N1 and the input node P5 are connected to each other in a direct current manner.

As illustrated in FIGS. 2, 3, 9 and 11, in the coupler 20, a first line (the line 41, the bonding wires 43 and 43c) is electrically connected to the node N1 and the input node P5. A second line (the line 42, the bonding wires 44 and 43b) is electrically connected to the node N2, is not electrically connected to the first line, and is electromagnetic-field coupled to the first line. This allows the electromagnetic field coupling between the node N2 and the input node P5 through the coupler 20.

The processing circuit 22 includes the capacitor C1 connected in series between the input node P5 and the reference potential. Thus, the processing circuit 22 can suppress the signals in the low frequency band of the amplifiers 10 and 12.

An absolute value ZL1 of the impedance at the center frequency of the operating band between the node N1 and the capacitor C1 is larger than an absolute value ZC of the impedance of the capacitor C1 at the frequency corresponding to the bandwidth of the operating band. An absolute value ZL2 of the impedance at the center frequency of the operating band between the node N2 and the capacitor C1 is larger than the absolute value ZC of the impedance of the capacitor C1 at the frequency corresponding to the bandwidth of the operating band. Thus, the leakage of the signals in the operating band in signals S3 and S4 to the reference potential can be suppressed, and the capacitor C1 can allow the signal in the low frequency band to pass through to the reference potential. Therefore, the insertion loss of the operating band of the amplifier 12 can be reduced. In addition, the isolation characteristics between the amplifiers 10 and 12 can be improved.

Each of the absolute values ZL1 and ZL2 can be 5 times or more, 20 times or more, or 50 times or more the absolute value ZC.

The center frequency of the operating band is, for example, 0.5 GHz to 10 GHZ, and 3.5 GHz as an example. The frequency of the low frequency band is, for example, 0 MHz to 500 MHz, and is 400 MHz as an example. In the first embodiment, when the lines L01 and L02 are inductors, the inductances of the lines L01 and L02 are, for example, 1 nH or more. Thus, the impedance of each of the lines L01 and L02 at the center frequency (3.5 GHZ) of the operating band becomes 22Ω. The impedance of each of the lines L01 and L02 at the center frequency of the operating band can be 5Ω or more, or can be 20Ω or more. When the lines L01 and L02 are transmission lines, the electrical lengths of the lines L01 and L02 are, for example, 24. Here, A is a wavelength at the center frequency of the operating band. Thereby, the signals in the operating band in the signals S3 and S4 do not propagate from the nodes N1 and N2 toward the lines L01 and L02. The electrical lengths of the lines L01 and L02 may be more than λ/8 and less than 3λ/8, and can be 3λ/16 or more and 5λ/16 or less, or 7λ/32 or more and 9λ/32 or less.

The capacitance of the capacitor C1 is, for example, 1 nF or more. Thereby, the impedance of the capacitor C1 at the frequency corresponding to the bandwidth of the operating band (400 MHZ) becomes 0.36Ω. The impedance of the capacitor C1 at the frequency corresponding to the bandwidth of the operating band can be 1Ω or more or 0.5Ω or more.

The amplifier 12 can operate with a lower input power than the amplifier 10. For example, the gate bias voltage VG2 is made larger in negative value than the gate bias voltage VG1. In this case, the distortion of the amplifier 12 is smaller than that of the amplifier 10. Therefore, by increasing the coupling degree between the node N1 and the input node P5, the asymmetry of the IMD3 of the amplifier 10 can be improved. By reducing the coupling degree between the node N2 and the input node P5, the insertion loss of the amplifier 12 with small distortion can be suppressed. In addition, the isolation characteristics between the amplifiers 10 and 12 can be improved. For example, the input power at which the amplifier 12 becomes operable can be lower by 1 dB or more or 3 dB or more than the input power at which the amplifier 10 becomes operable. For example, a difference between the gate bias voltages VG1 and VG2 is more than or equal to 1/10 or ⅕ of the pinch-off voltages of the amplifiers 10 and 12.

When the amplifier circuits 100 to 102 are Doherty amplifier circuits, the amplifier 10 is a peak amplifier and the amplifier 12 is a main amplifier. The amplifier 12 performs class AB or class B operation, and the amplifier 10 performs class C operation. When the input power of the input signal Sin is small, the amplifier 12 mainly amplifies the input signal Sin. When the input power is increased, the amplifier 10 amplifies the peak of the input signal Sin in addition to the amplifier 12. Thereby, the amplifiers 10 and 12 amplify the input signal Sin.

The amplifier 10 has a large distortion because of the class C operation. Therefore, by electrically connecting the node N1 to the processing circuit 22, the asymmetry of the MD3 of the amplifier 10 can be improved. By coupling the node N2 to the processing circuit 22 through the electromagnetic field coupling in the coupler 20, the insertion loss of the main amplifier can be suppressed. In addition, the isolation characteristics between the main amplifier and the peak amplifier can be improved.

### Second Embodiment

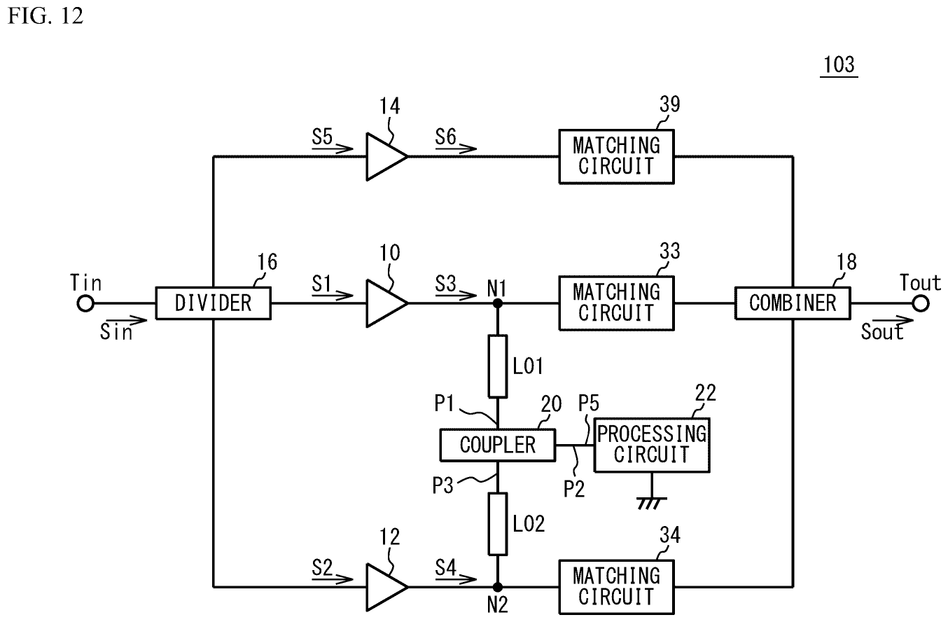

FIG. 12 is a block diagram of an amplifier circuit according to a second embodiment. In FIG. 12, the input matching circuits and the bias circuits are not illustrated. As illustrated in FIG. 12, in an amplifier circuit 103 of the second embodiment, the divider 16 divides the input signal Sin into signals S1, S2 and S5. An amplifier 14 (third amplifier) amplifies the signal S5 (fifth signal) and outputs an amplified signal S6 (sixth signal). The signal S6 amplified by the amplifier 14 passes through a matching circuit 39 and is output to the combiner 18. The matching circuit 39 matches an impedance when the matching circuit 39 is seen from the amplifier 14 with an impedance when the combiner 18 is seen from the matching circuit 39. The combiner 18 combines the signals S3, S4 and S6 and outputs a combined signal as the output signal Sout. In this way, the VBW circuit 24 may be provided for at least two amplifiers 10 and 12 of the amplifier circuit 103 including the three amplifiers 10, 12 and 14, and the signal in the low frequency band may be suppressed. The other configurations of the second embodiment are the same as those of the first embodiment, and the description thereof is omitted.

In the second embodiment, no node connected to the input node P5 of the processing circuit 22 is provided between the amplifier 14 and the combiner 18. This allows the amplifier circuit 103 to be downsized when the VBW circuit 24 is not required to be provided for the amplifier 14. In addition, the insertion loss of the amplifier 14 can be suppressed. The isolation characteristics between the amplifier 14 and the amplifiers 10 and 12 can be improved.

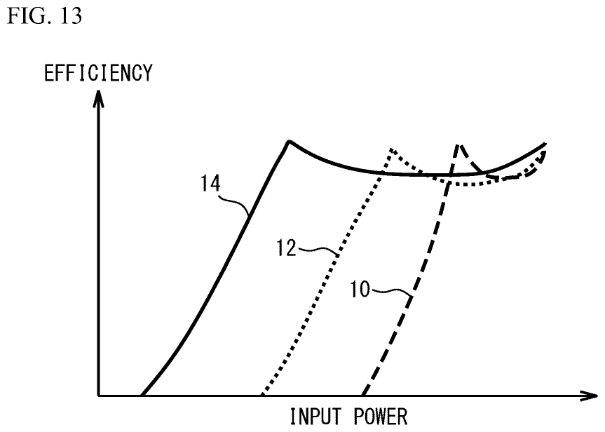

FIG. 13 is a diagram illustrating drain efficiencies of the amplifiers with respect to input power in the second embodiment. As illustrated in FIG. 13, when the input power increases, the amplifier 14 starts to operate. The amplifier 12 starts to operate in the vicinity of the input power where the drain efficiency of the amplifier 14 is maximized. The amplifier 10 starts to operate in the vicinity of the input power where the drain efficiency of the amplifier 12 is maximized. When the amplifiers 10, 12 and 14 are at saturation power, the drain efficiencies of the amplifiers 10, 12 and 14 are maximized. Thus, the amplifier 12 can operate with a lower input power than the amplifier 10, and amplifier 14 can operate with a lower input power than the amplifier 12. Such an operation can be realized, for example, by making a gate bias voltage VG3 of the amplifier 14 larger in negative value than the gate bias voltage VG2 of the amplifier 12, and making the gate bias voltage VG2 of the amplifier 12 larger in negative value than the gate bias voltage VG1 of the amplifier 10. In this case, the distortion of the amplifier 14 is smaller than the distortion of the amplifier 12, and the distortion of the amplifier 12 is smaller than the distortion of the amplifier 10. For this reason, the VBW circuit 24 may not be provided for the amplifier 14. Therefore, the insertion loss of the amplifier 14 having a small distortion can be suppressed. The isolation characteristics between the amplifier 14 and the amplifiers 10 and 12 can be improved.

### First Modification of Second Embodiment

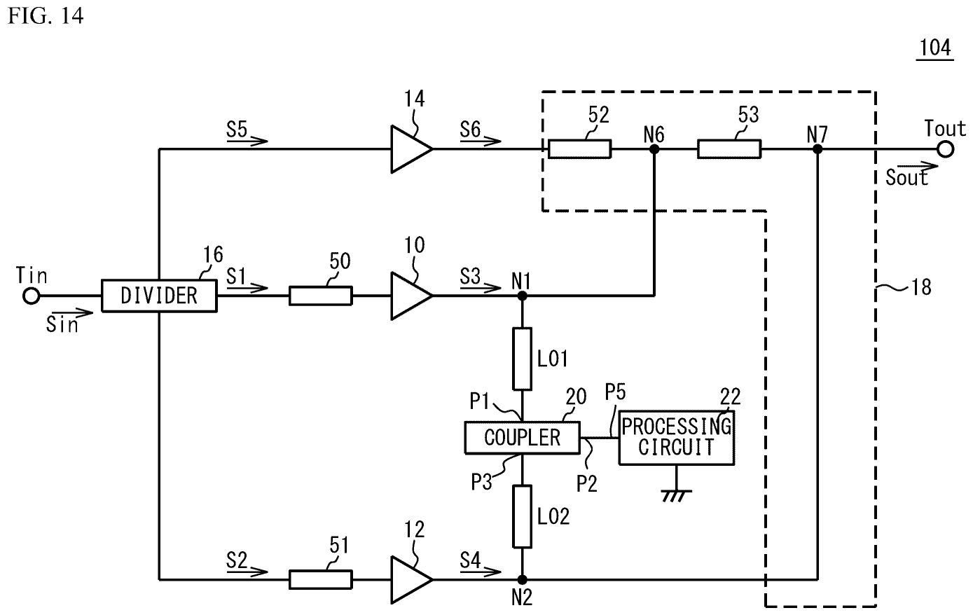

The first modification of the second embodiment is an example of a Doherty amplifier circuit. FIG. 14 is a block diagram of an amplifier circuit according to a first modification of the second embodiment. In FIG. 14, the matching circuits and the bias circuits are not illustrated, and the transmission line is illustrated.

An amplifier circuit 104 of the first modification of the second embodiment is the Doherty amplifier circuit, the amplifier 14 is the main amplifier, and the amplifiers 10 and 12 are peak amplifiers. A transmission line 50 is electrically connected between the divider 16 and the amplifier 10, and a transmission line 51 is electrically connected between the divider 16 and the amplifier 12. The combiner 18 includes transmission lines 52 and 53. The transmission line 52 is electrically connected between the amplifier 14 and a node N6 at which the signals S3 and S6 are combined. The transmission line 53 is provided between the node N6 and a node N7 where the signals S3, S6 and S4 are combined.

The characteristic impedances of the transmission lines 50 and 51 are the reference impedance R0 (e.g., 50Ω). The length of the transmission line 50 is λ/4, and the length of the transmission line 51 is λ/2. The transmission lines 52 and 53 are impedance conversion circuits, and the lengths of the transmission lines 52 and 53 are λ/4. The characteristic impedances of the transmission lines 52 and 53 are appropriately set according to the impedance to be converted. The transmission lines 50 and 51 are used for adjusting the phases shifted by the transmission lines 52 and 53. The other configuration of FIG. 14 is the same as that of FIG. 12 of the second embodiment, and the description thereof is omitted.

As in the first modification of the second embodiment, when the amplifier circuit 104 is the Doherty amplifier circuit, the amplifier 14 is the main amplifier, and the amplifiers 10 and 12 are the peak amplifiers. In this case, the amplifier 14 operates in class A or class B, and the amplifiers 10 and 12 operate in class C. The drain efficiencies of the respective amplifiers with respect to the input power are the same as, for example, the drain efficiencies of the respective amplifiers with respect to the input power in FIG. 13. Therefore, the distortion of the amplifier 14 is smaller than that of the amplifiers 10 and 12. Therefore, the VBW circuit 24 is not provided for the amplifier 14. This makes it possible to suppress insertion loss of the main amplifier. In addition, the isolation characteristics between the main amplifier and the peak amplifiers can be improved.

### Third Embodiment

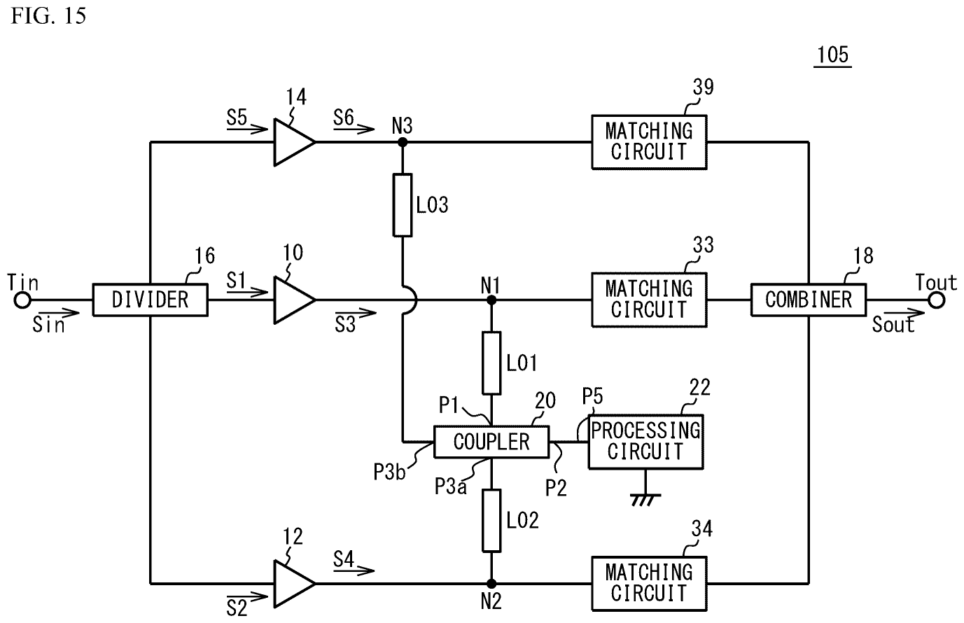

FIG. 15 is a block diagram of an amplifier circuit according to a third embodiment. In FIG. 15, the input matching circuits and the bias circuits are not illustrated. As illustrated in FIG. 15, in an amplifier circuit 105 of the third embodiment, the coupler 20 includes two coupling ports P3a and P3b. The second end of the line L02 is electrically connected to the coupling port P3a. A first end of the line L03 is electrically connected to a node N3 (third node) between the amplifier 14 and the matching circuit 39, and a second end of the line L03 is electrically connected to the coupling port P3b. The other configuration of FIG. 15 is the same as that of FIG. 12 of the second embodiment, and the description thereof is omitted.

An absolute value of an impedance of the line L03 at the center frequency of the operating band is made larger than the absolute value of the impedance of the capacitor C1 at the frequency corresponding to the bandwidth of the operating band. Thus, the line L03 can suppress the leakage of the signal in the operating band in the signal S6 to the reference potential, and the capacitor C1 can allow the signal in the low frequency band to pass through to the reference potential.

According to the third embodiment, the node N3 and the input node P5 of the processing circuit 22 are electrically coupled to each other. A coupling degree between the node N3 and the input node P5 is smaller than the coupling degree between the node N2 and the input node P5. This allows the VBW circuit 24 to be connected to the amplifier 14, and the signals in the low frequency band of the amplifiers 10, 12, and 14 can be suppressed. In addition, the insertion loss of the amplifier 14 can be suppressed. The isolation characteristics between the amplifier 14 and the amplifiers 10 and 12 can be improved.

A difference between the coupling degree between the node N2 and the input node P5 and the coupling degree between the node N3 and the input node P5 can be 1 dB or more, 2 dB or more, or 5 dB or more. From the viewpoint of coupling the node N3 and the input node P5, a difference between the coupling degree between the node N1 and the input node P5 and the coupling degree between the node N3 and the input node P5 can be set to 20 dB or less. The coupling degree between the node N3 and the input node P5 is, for example, 5 dB or less, or 10dB or less.

If the distortion of the amplifier 12 is greater than the distortion of the amplifier 14, the amplifier 14 can operate with a lower input power than the amplifier 12, for example. As a result, the signal in the low frequency band of the amplifier 14, in which the distortion is less likely to be a problem, is not suppressed more than the signal in the low frequency band of the amplifier 12, and the insertion loss in the amplifier 14 can be reduced. In addition, the isolation characteristics between the amplifier 14 and the amplifiers 10 and 12 can be improved.

When the amplifier circuit 105 is, for example, the Doherty amplifier circuit as in the first modification of the second embodiment, the amplifier 14 is the main amplifier, and the amplifiers 10 and 12 are the peak amplifiers. This makes it possible to suppress the loss of the main amplifier. In addition, the isolation characteristics between the main amplifier and the peak amplifiers can be improved.

In the second embodiment, its modification, and the third embodiment, the connection relationship between the coupler 20 and the processing circuit 22 may be the same as the connection relationship between the coupler 20 and the processing circuit 22 in the first and second modifications of the first embodiment.

### Simulation

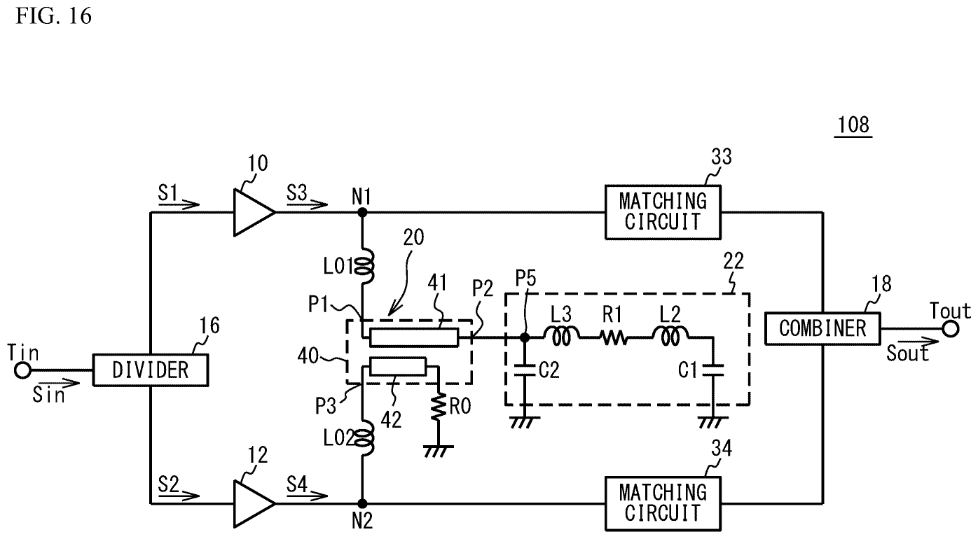

A simulation was performed for the first embodiment. FIG. 16 is a diagram illustrating an amplifier circuit in the simulation. As illustrated in FIG. 16, in an amplifier circuit 108, inductors are provided as the lines L01 and L02. As illustrated in FIG. 2, the lines 41 and 42 provided on the dielectric substrate 40 as the coupler 20. As in FIG. 6, the inductors L2 and L3, the capacitors C1 and C2, and the resistor RI are provided as the processing circuit 22. The amplifiers 10 and 12 are GaN HEMTs, and the gate bias voltages VG1 and VG2 are the same as each other. The center frequency of the pass band is 2.1 GHZ, and the frequency suppressed by the VBW circuit 24 is 300 MHz.

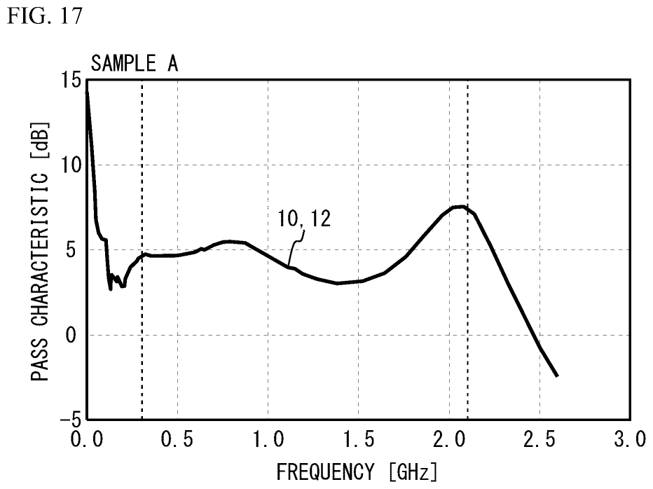

A sample A is the first comparative example in which the second ends of the lines L01 and L02 are connected to the processing circuit 22 without providing the coupler 20 as illustrated in FIG. 7. A sample B is the amplifier circuit 108 of the first embodiment illustrated in FIG. 16. FIG. 17 is a diagram illustrating pass characteristics of the sample A in the simulation. The pass characteristics are the gains from the divider 16 to the combiner 18 that pass from the amplifiers 10 and 12. As illustrated in FIG. 17, the amplifiers 10 and 12 have the same pass characteristics. At 2.1 GHz which is the center frequency of the pass band, the gains of the amplifiers 10 and 12 are 7.417 dB. At the frequency of 300 MHz suppressed by the VBW circuit 24, the gains of the amplifiers 10 and 12 can be reduced to 4.785 dB.

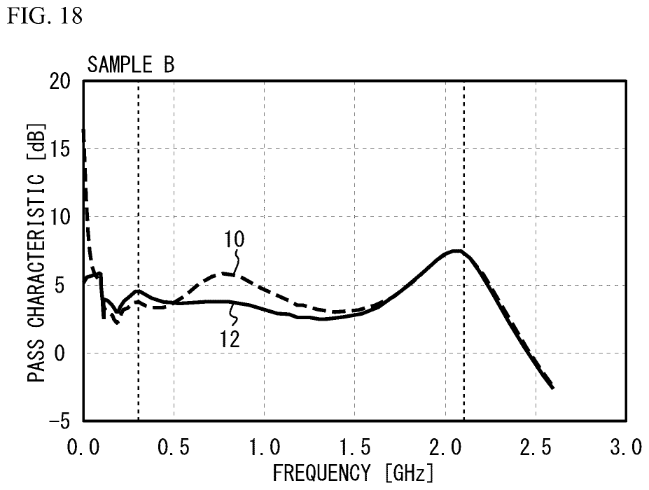

FIG. 18 is a diagram illustrating pass characteristics of the sample B in the simulation. The pass characteristic is a gain from the divider 16 to the combiner 18. As illustrated in FIG. 18, the gains of the amplifiers 10 and 12 at 2.1 GHZ are 7.323 dB and 7.404 dB, respectively, and the gain of the amplifier 12 is slightly larger than that of the amplifier 10. The gains of the amplifiers 10 and 12 at 300 MHz are 3.999 dB and 4.768 dB, respectively, and the gain of the amplifier 10 is larger than that of the amplifier 12. In this way, the signal in the low frequency band of the amplifier 10 can be suppressed, and the loss in the operating band of the amplifier 12 can be suppressed.

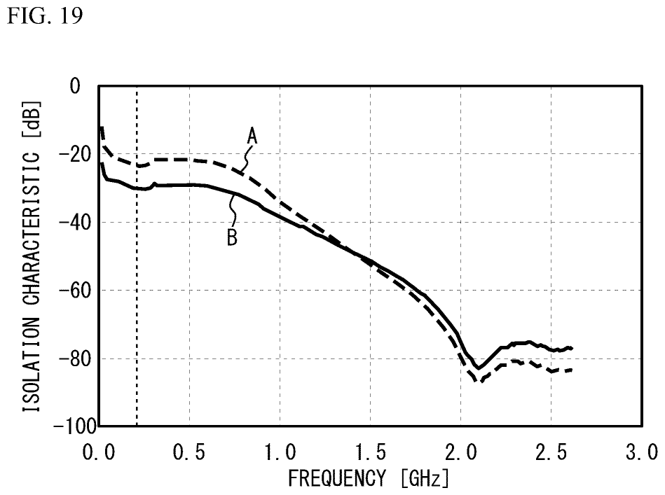

FIG. 19 is a diagram illustrating isolation characteristics of the samples A and B in the simulation. The isolation characteristic is the isolation between the nodes N1 and N2. In one example, an improvement in isolation characteristics at 200 MHz, at which the amplifier circuit is likely to oscillate, is required. As illustrated in FIG. 19, the isolation characteristics of the samples A and B at 200 MHz are −23 dB and −30 dB, respectively, and the isolation characteristics of the sample B provided with the coupler 20 can be improved.

As described in the above simulation, in the sample B provided with the coupler 20, the insertion loss of the amplifier 12 can be suppressed and the isolation characteristics between the nodes N1 and N2 can be improved as compared with the sample A provided with no coupler 20.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifier circuit comprising:
a divider that divides an input signal into a first signal and a second signal;
a first amplifier that amplifies the first signal and output an amplified signal to a first node as a third signal;
a second amplifier that amplifies the second signal and outputs an amplified signal to a second node as a fourth signal;
a combiner that combines the third signal and the fourth signal and outputs a combined signal to an output terminal as an output signal; and
a processing circuit that includes an input node to which the first node and the second node are electrically coupled, and allows a signal having a frequency lower than an operating band of the first amplifier and the second amplifier to pass through a reference potential, wherein a coupling degree between the first node and the input node is larger than a coupling degree between the second node and the input node.

2. The amplifier circuit according to claim 1, wherein
the first node and the input node are electrically connected to each other, and
the second node and the input node are electromagnetic-field coupled in a coupler.

3. The amplifier circuit according to claim 2, wherein
the coupler includes a first line electrically connected to the first node and the input node. and a second line electrically connected to the second node, not electrically connected to the first line, and electromagnetic-field coupled to the first line.

4. The amplifier circuit according to claim 1, wherein
the processing circuit includes a capacitor connected in series between the input node and the reference potential.

5. The amplifier circuit according to claim 4, wherein
an absolute value of an impedance at a center frequency of the operating band between the first node and the capacitor is larger than an absolute value of an impedance of the capacitor at a frequency corresponding to a bandwidth of the operating band, and
an absolute value of an impedance at a center frequency between the second node and the capacitor is larger than the absolute value of the impedance of the capacitor at the frequency corresponding to the bandwidth of the operating band.

6. The amplifier circuit according to claim 1, wherein
the second amplifier is operable with a lower input power than the first amplifier.

7. The amplifier circuit according to claim 1, wherein
the amplifier circuit is a Doherty amplifier circuit,
the first amplifier is a peak amplifier, and
the second amplifier is a main amplifier.

8. The amplifier circuit according to claim 1, further comprising:
a third amplifier,
wherein the divider divides the input signal into the first signal, the second signal, and a fifth signal,
the third amplifier amplifies the fifth signal and outputs an amplified signal to a third node as a sixth signal, and
the combiner combines the third signal, the fourth signal, and the sixth signal, and outputs a combined signal as the output signal.

9. The amplifier circuit according to claim 8, wherein
a node electrically coupled to the input node is not provided between the third amplifier and the combiner.

10. The amplifier circuit according to claim 8, wherein
the third node and the input node are electrically coupled to each other, and
a coupling degree between the third node and the input node is smaller than the coupling degree between the second node and the input node.

11. The amplifier circuit according to claim 9, wherein
the second amplifier is operable with a lower input power than the first amplifier, and
the third amplifier is operable with a lower input power than the second amplifier.

12. The amplifier circuit according to claim 9, wherein
the amplifier circuit is a Doherty amplifier circuit,
the third amplifier is a main amplifier, and
the first amplifier and the second amplifier are peak amplifiers.
